(19) United States
(12) Patent Application Publication
(10) Pub. No.: US 2018/0212043 A1
(43) Pub. Date: Jul. 26, 2018

(54) METHOD FOR MANUFACTURING THIN FILM TRANSISTOR

(71) Applicant: Wuhan China Star Optoelectronics Technology Co. Ltd., Wuhan, Hubei (CN)

(72) Inventor: Tao Sun, Wuhan, Hubei (CN)

(73) Assignee: Wuhan China Star Optoelectronics Technology Co., Ltd., Wuhan, Hubei (CN)

(21) Appl. No.: 15/327,470

(22) PCT Filed: Dec. 29, 2016
(86) PCT No.: PCT/CN2016/113155

§ 371 Date: Jan. 19, 2017

(30) Foreign Application Priority Data
Dec. 27, 2016 (CN) 201611227216.7

(51) Int. Cl. H01L 29/66; H01L 27/12; H01L 29/417; H01L 29/786

(52) U.S. Cl. CPC H01L 29/66765; H01L 27/1288; G02F 1/133345; H01L 29/41733; H01L 29/786; H01L 27/127

(57) ABSTRACT

Disclosed is a method for manufacturing a thin film transistor. The method includes steps of etching a second metal layer and a semiconductor layer to form a boundary region of a thin film transistor; etching the second metal layer again to form a source, a drain and a back channel region of the thin film transistor; removing residual photoresist via an ashing procedure; and etching the semiconductor layer again to form a conductive channel of the thin film transistor. According to the method, the electric leakage problem of thin film transistor due to diffusion of copper and contamination of organic stripping liquid can be eliminated.

### CROSS-REFERENCE TO RELATED APPLICATIONS

This application claims the priority of Chinese patent application CN201611227216.7, entitled “Method for manufacturing thin film transistor” and tiled on Dec. 27, 2016, the entirety of which is incorporated herein by reference.

### FIELD OF THE INVENTION

The present disclosure relates to the technical field of liquid crystal display, and in particular, to a method for manufacturing a thin film transistor.

### BACKGROUND OF THE INVENTION

With the development of flat panel display (FPD) technology, people's requirements for display resolution and refresh rate of image become higher and higher. Therefore, the development of new materials and new technologies is also imminent.

At present, in the field of thin film transistor liquid crystal display (TFT LCD) manufacturing, materials of conductive layer metal are mainly Al and Mo. Al and Mo have advantages in that, film-forming process thereof is simple and the adhesion and flatness thereof are quite good. They are quite soft, not prone to break while climbing, and not easy to diffuse (diffusion leads to film contamination). For panel of small size and low resolution, Al is a preferred conductive metal material. However, since resistivity of Al is relatively large, for panel of large size and high resolution, the requirement thereof cannot be satisfied.

As a conductive metal material, electrical conductivity of Cu is much higher than that of Al. For a 15-inch UXGA (Ultra extended Graphics Array) display screen, if Cu is used as a conductive metal material instead of Al, a panel resolution can be increased by 35.2%, brightness can be increased by 32%, and screen flicker and wire loading can be greatly reduced. Hence, aiming at the current market demand of high-resolution display panel, Cu will be used in the future display panel instead of Al.

In the aluminum processing technology and the copper processing technology of conventional back channel-etch type TFT, leakage current control of back channel-etch type TFT is always a difficulty in the process. Especially in the copper processing technology, the electric leakage problem caused by pollution of back channel is more obvious. As a result, copper has not replaced Al completely during manufacturing of flat display panel yet. In order to solve the electric leakage problem in the copper process, in the prior art, the metal of buffer layer in metal electrode is replaced by other kinds of metal, such as Ti, TiNd, MoTi or Mo. Meanwhile, the leakage current can be reduced by shortening the process wait time. The aforesaid process renders that it is quite rigorous to change a condition of mass production of the display panel. Therefore, a mass production development period of copper process of the display panel will be affected and the difficulty of mass production will be increased.

### SUMMARY OF THE INVENTION

The present disclosure aims to alleviate an electric leakage problem in copper process, which is conducive to shortening mass production development period of copper process of a display panel.

In order to solve the above technical problem, the embodiments of the present application provide a method for manufacturing a thin film transistor, which comprises steps of: forming a first metal layer on a substrate, and patterning the first metal layer to form a gate of a thin film transistor; forming a gate insulating layer on the gate; forming a semiconductor layer and a second metal layer in sequence on the gate insulating layer; coating a photoresist on the second metal layer; etching the second metal layer and the semiconductor layer to form a boundary region of the thin film transistor; etching the second metal layer again to form a source, a drain and a back channel region of the thin film transistor; removing residual photoresist via an ashing procedure; and etching the semiconductor layer again to form a conductive channel of the thin film transistor.

Preferably, the first metal layer and the second metal layer are formed, and the first metal layer and the second metal layer are both composite layers comprising copper material and metal material of a buffer layer.

Preferably, the step of removing residual photoresist via an ashing procedure specifically comprises sub steps of: treating the photoresist with a mixture of sulfur hexafluoride and oxygen during a first half of the ashing procedure; and treating the photoresist with oxygen during a second half of the ashing procedure.

Preferably, a volume ratio of sulfur hexafluoride to oxygen in the mixture is in a range from 1:1 to 1:7.

Preferably, after the step of coating a photoresistis on the second metal layer, the method further comprises a step of: patterning the photoresist with a gray-tone photomask to remove a part of the photoresist corresponding to the back channel region of the thin film transistor.

Preferably, the step of etching the second metal layer and the semiconductor layer to form a boundary region of the thin film transistor specifically comprises sub steps of: etching the second metal layer by a wet etching technology; and etching the semiconductor layer by a dry etching technology.

Preferably, before the step of etching the second metal layer again to form a source, a drain and a back channel region of the thin film transistor, the method further comprises a step of: removing a partial thickness of the photoresist via an ashing procedure.

Preferably, the semiconductor layer is etched again with carbon tetrafluoride or carbon tetrachloride to form the conductive channel of the thin film transistor.

Preferably, the first metal layer and the second metal layer are formed by a physical sputtering technology.

Preferably, the gate insulating layer is formed by a plasma enhanced chemical vapor deposition technology

Compared with the prior art, one embodiment or more embodiments of the above technical solution can have the following advantages or beneficial effects.

Through optimizing the processing flow of thin film transistor in the copper process of display panel, electric leakage problem of thin film transistor due to diffusion of copper and the contamination of an organic stripping liquid can be solved.

Other advantages, objectives and characteristics of the present disclosure will be further explained in the following description, and to a certain extent, these will be apparent to those skilled in the art based on the study of the following texts, or may be taught from the practice of the present invention. The objectives and other advantages of the present disclosure will be achieved through the structure specifically pointed out in the following description, claims, and the accompanying drawings.

### BRIEF DESCRIPTION OF THE DRAWINGS

The accompanying drawings provide further understandings of the technical solution of the present disclosure or the prior art, and constitute one part of the description. The accompanying drawings expressing the embodiments of the present application are used for interpreting the technical solutions of the present application together with the embodiments, not for limiting the technical solutions of the present application. In the drawings:

FIG. 1 schematically shows a structure of film layers of a thin film transistor of a display panel;

FIG. 2 is a flow chart of a method for manufacturing a thin film transistor according to one embodiment of the present disclosure;

FIGS. 3a to 3h schematically show technological processes of the thin film transistor according to one embodiment of the present disclosure; and

FIG. 4 is a flow chart of a step of removing residual photoresist via an asking procedure according to one embodiment of the present disclosure.

### DETAILED DESCRIPTION OF THE EMBODIMENTS

The present disclosure will be explained in details with reference to the embodiments and the accompanying drawings, whereby it can be fully understood how to solve the technical problem by the technical means according to the present disclosure and achieve the technical effects thereof, and thus the technical solution according to the present disclosure can be implemented. All the technical features mentioned in all the embodiments, as long as there is no structural conflict, may be combined together in any manner, and the technical solutions obtained in this manner all fall within the scope of the present disclosure.

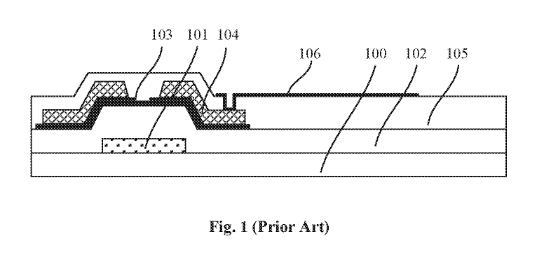

FIG. 1 schematically shows a structure of film layers of a thin film transistor of a display panel. As shown in FIG. 1, 100 is a glass substrate of the display panel. From bottom to top, the structure of the film layers comprises a gate 101 of the thin film transistor (i.e. a first metal layer), a gate insulating layer 102, a semiconductor layer 103, and a source and a drain 104 of the thin film transistor (i.e. a second metal layer) in sequence. An insulating protective layer 105 is covered on the aforesaid thin film transistor structure, and the insulating protective layer 105 is provided with a via hole. A pixel electrode 106 is connected to the source or the drain of the thin film transistor through the via hole.

In copper process of manufacturing the thin film transistor with the aforesaid structure, a step causing leakage of current mainly lies in etching of a conductive channel. According to the embodiment of the present disclosure, the process of the conductive channel is improved on the basis of that in the prior art, which will be illustrated hereinafter combining specific embodiments.

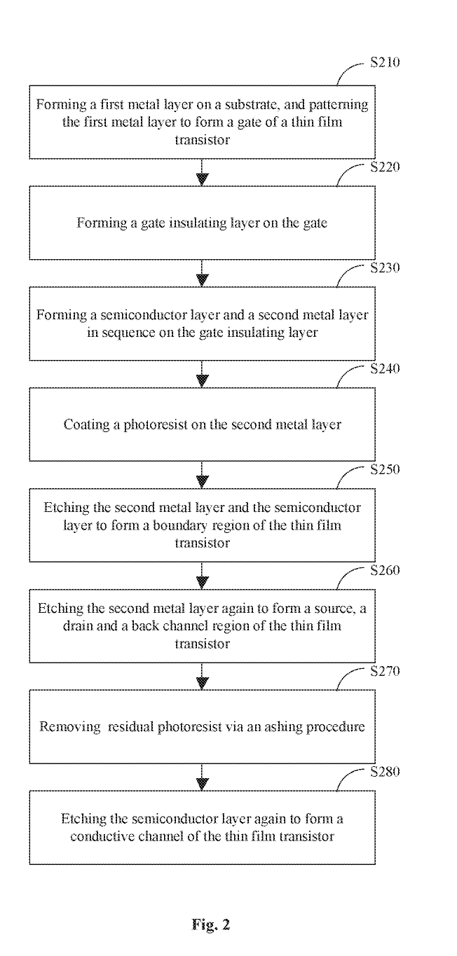

FIG. 2 is a workflow of a method for manufacturing a thin film transistor according to the embodiment of the present disclosure. As shown in FIG. 2, the method comprises following steps.

In step S210, a first metal layer is formed on a substrate, and the first metal layer is patterned to form a gate of a thin film transistor.

In step S220, a gate insulating layer is formed on the gate.

In step S230, a semiconductor layer and a second metal layer are formed in sequence on the gate insulating layer.

In step S240, a photoresistis coated on the second metal layer.

In step S250, the second metal layer and the semiconductor layer are etched to form a boundary region of the thin film transistor.

In step S260, the second metal layer is etched again to form a source, a drain and a back channel region of the thin film transistor.

In step 270, residual photoresist is removed via an ashing procedure.

In step 280, the semiconductor layer is etched again to form a conductive channel of the thin film transistor.

Specifically, in step S210, the first metal layer is deposited on the substrate by a physical sputtering method so as to form the gate of the thin film transistor. The physical sputtering method refers to a physical film formation method through which targets are bombarded with gas ions accelerated by an electric field, and film forming materials are transferred from the targets to the substrate.

For example, a Mo a layer and a Cu layer are deposited by the physical sputtering method in sequence, and thicknesses of the Mo layer and the Cu layer are respectively in a range from 100 Å to 300 Å and in a range from 3000 Å to 6000 Å.

In general, a metal electrode of the thin film transistor is a buffer layer structure. Specifically, composite film layers are formed by buffer layer metal materials and copper materials. The use of the composite film layers comprising the copper materials and the buffer layer metal materials can prevent diffusion of copper into an active layer. In the prior art, the electric leakage problem in the copper process is mainly solved by changing the metal of the buffer layer, but a condition of mass production in the process will become more rigorous.

According to one embodiment of the present disclosure, only common metal materials are used as a buffer layer, for example, Ti/Mo/Cu can also be used to form the first metal layer. In addition, all process parameters in the prior art can be used in the present embodiment, and related manufacturing procedures in the prior art can be used in the present embodiment without alteration.

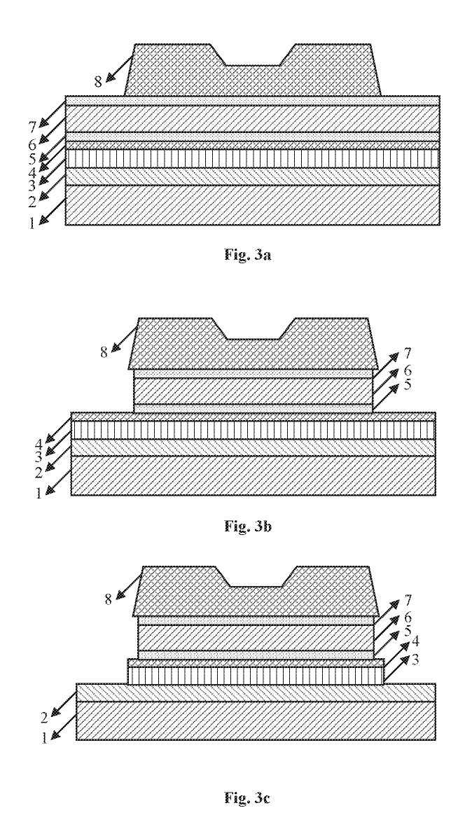

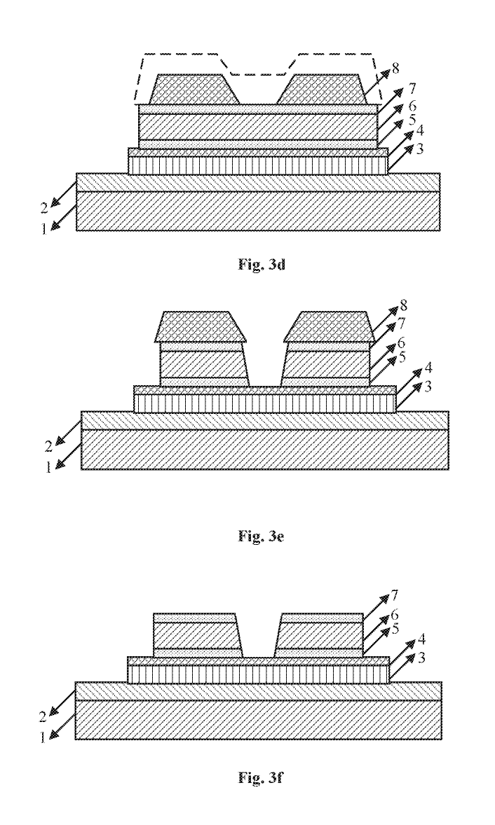

Next, the first metal layer is patterned by coating, exposing, developing, wet etching, removing and other procedures to form a gate metal structure of the thin film transistor. The specific implementations of the aforesaid procedures and the selection of process parameters can be obtained according to the related processes in the prior art, and are not repeated here. The gate of the thin film transistor obtained after patterning is shown as a film layer 1 in FIG. 3a, and the structure of the composite layer is represented schematically by only one film layer.

In step S220, one SiNx layer is deposited by a plasma enhanced chemical vapor deposition (PECVD) method to form the gate insulating layer. The PECVD method mainly refers to a method in which a low temperature plasma is produced by energizing gases and the chemical activity of reaction materials is increased so as to grow epitaxially. In general, a thickness of the SiNx layer can be selected from 2000 Å to 5000 Å. The gate insulating layer is shown as a film layer 2 in FIG. 3a.

In step S230, the semiconductor layer is deposited by the PECVD method.

According to one embodiment of the present disclosure, the semiconductor layer comprises an amorphous silicon layer and a doped amorphous silicon layer. Film thicknesses of the amorphous silicon layer and the doped amorphous silicon layer can be selected according to the process parameters in the prior art. For example, the film thicknesses of the amorphous silicon layer and the doped amorphous silicon layer are both in a range from 1300 Å to 2000 Å.

As shown in FIG. 3a, a film layer 3 represents the amorphous silicon layer, and a film layer 4 represents the doped amorphous silicon layer.

Then, the second metal layer is deposited by a physical sputtering method to form the source and the drain of the thin film transistor. This process is similar to the process of forming the first metal layer.

For example, according to one embodiment of the present disclosure, a Mo/Ti layer, a Cu layer and a Mo/Ti layer are deposited by a physical sputtering method in sequence. Film thicknesses of the Mo/Ti metal layer and the Cu layer are respectively in a range from 100 Å to 300 Å, and in a range from 3000 Å to 6000 Å.

As shown in FIG. 3a, a film layer 5 and a film layer 7 both represent the Mo/Ti layer, and a film layer 6 represents the Cu layer.

In step S240, the photoresist is coated on the second metal layer. The photoresist is a kind of light resistance material. Before the metal layer is etched, a part thereof which does not need to be etched should be protected, and one layer of photoresist with uniform thickness and strong adhesion is covered thereon, so that the subsequent exposing, developing and other procedures can obtain a good pattern forming effect.

After the photoresist is coated on the second metal layer, a part of the photoresist corresponding to the back channel region of the thin film transistor should be removed. The stripping of the photoresist is a process of removing the photoresist using a stripping liquid. Generally, the substrate coated with the photoresist is put into the stripping liquid, and components in the stripping liquid are impregnated into an interface between the photoresist and the film layer. The photoresist is decomposed, and then dissolved in the stripping liquid.

As shown in FIG. 3a, a film layer 8 is a photoresist layer formed finally, and a concave part thereof corresponds to the back channel region of the thin film transistor.

During actual manufacturing procedure, the photoresist layer can be patterned using a gray-tone photomask. The process of the gray-tone photomask can be obtained with reference to the prior art, which is not repeated here.

The step S250 specifically comprises two sub steps. First the second metal layer (i.e., the film layers 5, 6, and 7) is etched by a wet etching technology, which is shown in FIG. 3b.

The wet etching technology is mainly a process that the film layer uncovered with the photoresist is chemically etched to form required patterns or wires by using different chemical solutions. Generally, a liquid which is highly chemically reactive with a thin film is used as the etching liquid, and a reaction product should be a substance which can be easily dissolved in water or in gas phase.

After the second metal layer is etched, the semiconductor layer (i.e., the film layers 3 and 4) is etched by a dry etching technology, which is shown in FIG. 3c.

The dry etching technology is mainly a process that the film layer uncovered with the photoresist is chemically etched to form required patterns or wires by using plasma. Generally, high-energy plasma is formed by introducing specific gases. High-energy ions or free radicals of the plasma diffuse to a surface of an unprotected film, and a chemical reaction occurs. A reaction product is also a gas.

The boundary region of the thin film transistor is formed by etching the second metal layer and the semiconductor layer respectively.

In the following step S260, first the photoresist film layer is treated. A partial thickness of the photoresist is removed via an ashing procedure, so that the second metal layer corresponding to the back channel region of the thin film transistor can be exposed to facilitate the subsequent etching of the back channel region, which is shown in FIG. 3d.

It should be noted that, a gas used for the ashing procedure is a mixture of sulfur hexafluoride (SF6) and oxygen (O2). Moreover, a volume ratio of SF6 to O2 in the mixture is not defined, and process parameters in the prior art can be used.

Then the second metal layer is etched again to form the source, the drain and the back channel region. As shown in FIG. 3e, the second metal layer is also etched by the wet etching technology, and the process can be obtained with reference to the relevant content of the first etching of the second metal layer in step S250, which is not repeated here.

The source, the drain and the back channel region are formed by the second etching step.

In step S270, as shown in FIG. 3f, residual photoresist, which are mainly covered on the source and the drain, is removed via the ashing procedure.

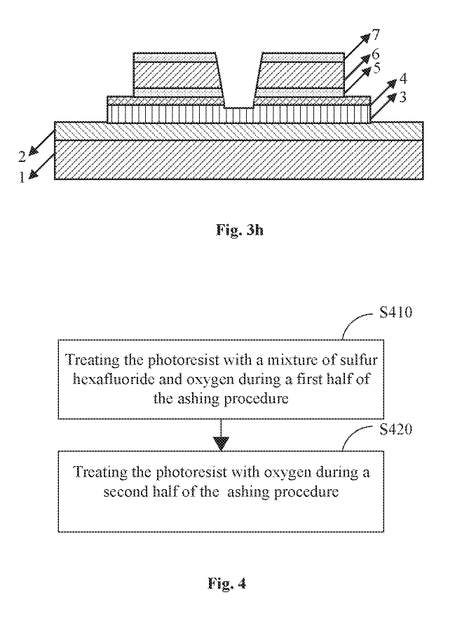

Further, as shown in FIG. 4, the step of removing residual photoresist via an ashing procedure specifically comprises sub steps of:

in step S410, during a first half of the ashing procedure, the photoresist is treated with a mixture of sulfur hexafluoride (SF6) and oxygen (O2); and

in step S420, during a second half of the ashing procedure, the photoresist is treated with oxygen (O2).

Specifically, the mixture of SF6 and O2 is conducive to improvement of an ashing rate and can accelerate the ashing procedure. Hence, during the first half of the ashing procedure, most part of photoresist can be rapidly removed by the mixture of SF6 and O2.

Meanwhile, it is discovered that, SF6, as a main supply source of F element, can react with the semiconductor layer, which can assist etching and increase the etching rate. However, SF6 is also the main reason for contamination of the thin film transistor channel. SF6 can react with a copper electrode to generate a sulfur-copper complex, which is easy to diffuse. If the sulfur-copper complex diffuses into the channel layer continuously, it will lead to the contamination of the conductive channel. Hence, according to the embodiment of the present disclosure, a content of SF6 is controlled by controlling a volume ratio of SF6 to O2 in an ashing gas so as to reduce the contamination of SF6 to the semiconductor channel.

During the second half of the ashing procedure, the photoresist is only treated with O2. O2 can substitute sulfur in the sulfur-copper complex to produce copper oxide. Copper oxide is not easy to diffuse and will not cause contamination to the semiconductor channel, so that a protective effect on the conductive channel is formed.

According to one embodiment of the present disclosure, a content of SF6 can be gradually reduced to 0 during the ashing procedure. In this manner, the speed of the ashing procedure can be ensured; the contamination of SF6 to the conductive channel can be eliminated; stability of the ashing procedure can be ensured; and the yield thereof can be improved.

According to another embodiment of the present disclosure, a volume ratio of SF6 to O2 in the mixture of SF6 and O2 is in a range from 1:1 to 1:6 or 1:7. That is, during the first half of the ashing procedure, the content of SF6 is controlled to avoid the contamination to the semiconductor channel.

Finally, in step S280, after the residual photoresist is removed, the semiconductor layer is etched for a second time to form the conductive channel of the thin film transistor, which is shown in FIG. 3h.

According to one embodiment of the present disclosure, the semiconductor layer is etched with carbon tetrafluoride (CF4) or carbon tetrachloride (CCl4).

In the prior art, a large amount of helium gas (He) is added during the etching of the conductive channel. The effect of helium is to homogenize the plasma, but helium affects a composite metal layer of the source and drain of the thin film transistor. Hence, according to the present embodiment, the semiconductor layer is etched only with CF4 and CCl4. As a main supply source of F element, CF4 is used to react with the semiconductor layer, assist the etching and increase the etching rate. As a main supply source of Cl element, CCl4 is used to etch the semiconductor layer.

According to the method for manufacturing the thin film transistor provided by the present disclosure, the residual photoresist is removed before the thin film transistor is etched, and finally the thin film transistor is asked with oxygen. In this manner, the condition of electric leakage caused by an organic stripping liquid contamination can be avoided; the electric leakage of the copper process array TFT component can be alleviated; and stability of electrical property and the electrical reliability of a product can be improved.

Generally, after the conductive channel of the thin film transistor is manufactured, a SiNx insulating protective layer with a thickness in a range from 2000 Å to 5000 Å is deposited by a PECVD method, and then a via hole structure is formed by coating, exposing, developing, dry etching, stripping and other procedures.

After the insulating protective layer is formed, a transparent conductive layer such as ITO with a thickness in a range from 300 Å to 1000 Å is deposited by a physical sputtering method, and then a pixel electrode structure is formed by coating, exposing, developing, wet etching, stripping and other procedures.

The above embodiments are described only for better understanding, rather than restricting, the present disclosure. Any person skilled in the art can make amendments to the implementing forms or details without departing from the spirit and scope of the present disclosure. The protection scope of the present disclosure shall be determined by the scope as defined in the claims.

1. A method for manufacturing a thin film transistor, comprising steps of:
forming a first metal layer on a substrate, and patterning the first metal layer to form a gate of the thin film transistor;
forming a gate insulating layer on the gate;
forming a semiconductor layer and a second metal layer in sequence on the gate insulating layer;
coating a photoresist on the second metal layer;
etching the second metal layer and the semiconductor layer to form a boundary region of the thin film transistor;
etching the second metal layer again to form a source, a drain and a back channel region of the thin film transistor;
removing residual photoresist via an ashing procedure; and
etching the semiconductor layer again to form a conductive channel of the thin film transistor.

2. The method according to claim 1, wherein the first metal layer and the second metal layer are formed, and the first metal layer and the second metal layer are both composite layers comprising copper materials and metal materials of a buffer layer.

3. The method according to claim 1, wherein the step of removing residual photoresist via an ashing procedure specifically comprises sub steps of:
treating the photoresist with a mixture of sulfur hexafluoride and oxygen during a first half of the ashing procedure; and
treating the photoresist with oxygen during a second half of the ashing procedure.

4. The method according to claim 3, wherein a volume ratio of sulfur hexafluoride to oxygen in the mixture is in a range from 1:1 to 1:7.

5. The method according to claim 1, wherein after the step of coating a photoresist on the second metal layer, the method further comprises a step of:
patterning the photoresist with a gray-tone photomask to remove a part of the photoresist corresponding to the back channel region of the thin film transistor.

6. The method according to claim 5, wherein the step of etching the second metal layer and the semiconductor layer to form a boundary region of the thin film transistor specifically comprises sub steps of:
etching the second metal layer by a wet etching technology and
etching the semiconductor layer by a dry etching technology.

7. The method according to claim 6, wherein before the step of etching the second metal layer again to form a source, a drain and a back channel region of the thin film transistor, the method further comprises a step of:
removing a partial thickness of the photoresist via an ashing procedure.

8. The method according to claim 1, wherein the semiconductor layer is etched again with carbon tetrafluoride or carbon tetrachloride to form the conductive channel of the thin film transistor.

9. The method according to claim 1, wherein the first metal layer and the second metal layer are formed by a physical sputtering technology.

10. The method according to claim 1, wherein the gate insulating layer is formed by a plasma enhanced chemical vapor deposition technology.
